(19) United States
(12) Patent Application Publication
(10) Pub. No.: US 2025/0014806 A1
(43) Pub. Date: Jan. 9, 2025

(54) COMMON MODE FILTERING DEVICE AND CHARGING SYSTEM FOR ELECTRIC OR HYBRID VEHICLES

(71) Applicant: ELDOR CORPORATION S.P.A., Orsenigo (Como) (IT)

(72) Inventors: Pasquale FORTE, Orsenigo (Como) (IT); Stefano SILVA, Orsenigo (Como) (IT)

(21) Appl. No.: 18/710,994

(22) PCT Filed: Nov. 15, 2022
(86) PCT No.: PCT/IB2022/060960

§ 371 Date: May 16, 2024

(30) Foreign Application Priority Data
Nov. 17, 2021 (IT) 102021000029060

(51) Int. Cl. H01F 27/28; G01R 33/04; H01F 17/00; H01F 17/06; H01F 27/32; H01F 27/40; H01F 37/00

(52) U.S. Cl. CPC H01F 27/2895; H01F 17/062; H01F 27/325; H01F 27/402; H01F 37/00; G01R 33/04; H01F 2017/0093

(57) ABSTRACT

A common mode current filter includes a magnetic core, multiple electrical windings, each extending between two ends and including multiple coils wound around the magnetic core, and a fluxgate magnetometer positioned inside the coils of each electrical winding.

This invention relates to a common mode current filter and a system for charging electric or hybrid vehicles comprising said device.

The main application for this invention is, thus, in the automotive sector, in particular in the design and manufacture of systems for charging electric batteries.

In electronics, and in the automotive sector, it is known to use common mode inductors to prevent electromagnetic interference (EMI) and radio-frequency interference (RFI) from and to the power lines.

These devices, which take up significant space within known charging systems, at least in relation to the growing needs for miniaturisation and reduction in costs, are, therefore, essential elements along the charging line, though limiting, in fact, their usefulness merely to the filtering function.

There are, in any case, numerous other devices that, for design reasons linked to an increase in performance or safety, must or may be connected either to the network branch or to the charging branch of a system for charging electric batteries for automotive use, always entailing greater difficulties for designers that must combine the needs of reducing costs and size, with the growing necessity for components.

The purpose of this invention is, therefore, to provide a common mode current filter and a system for charging electric or hybrid vehicles that may avoid the drawbacks of the prior art mentioned above.

In particular, the purpose of this invention is to provide a common mode current filter that is highly efficient and has extended functionalities.

In addition, the purpose of this invention is to provide a system for charging electric or hybrid vehicles that is optimised in terms of the dimensions and costs of the components.

Said purposes are achieved with a common mode current filter and a system for charging electric or hybrid vehicles that have the features of one or more of the following claims.

In particular, said purposes are achieved with a common mode current filter comprising a magnetic core (preferably crystalline or nanocrystalline).

The presence of multiple electrical windings is also provided for, each extending between two ends and comprising multiple coils wound around the core. It should be noted that even a single coil per winding wound around the magnetic core may be sufficient, but for construction reasons and strength, it is preferable that there are multiple coils wound around the core, preferably in an equal number per winding.

According to the invention, the filter also comprises a fluxgate magnetometer positioned inside the coils of each electrical winding.

Advantageously, in this way it is possible to exploit the arrangement of the windings of the filter to detect useful current unbalances, even reduced, fulfilling the increasingly stringent standards on the safety of electric vehicles without negatively affecting neither the dimensions nor the cost of the system.

Additional features and advantages of this invention will be clearer from the indicative, and therefore non-limiting, description of one preferred, but not exclusive, embodiment of a common mode current filter and a system for charging electric or hybrid vehicles, as illustrated in the attached drawings wherein:

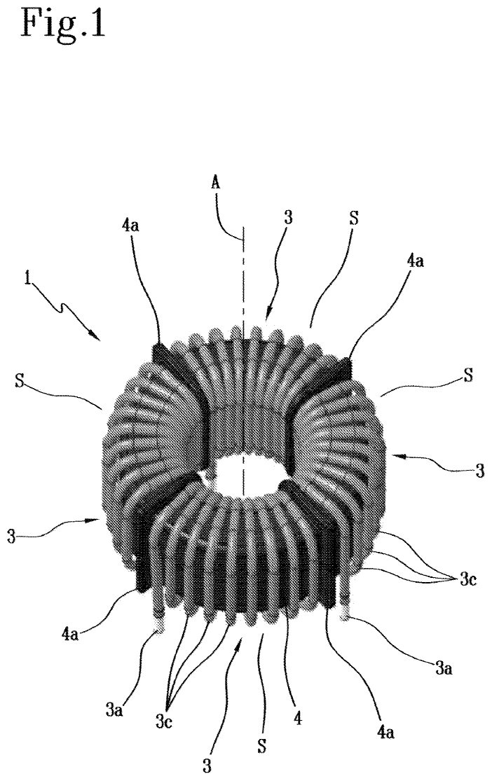

FIG. 1 shows a perspective view of a common mode current filter according to this invention;

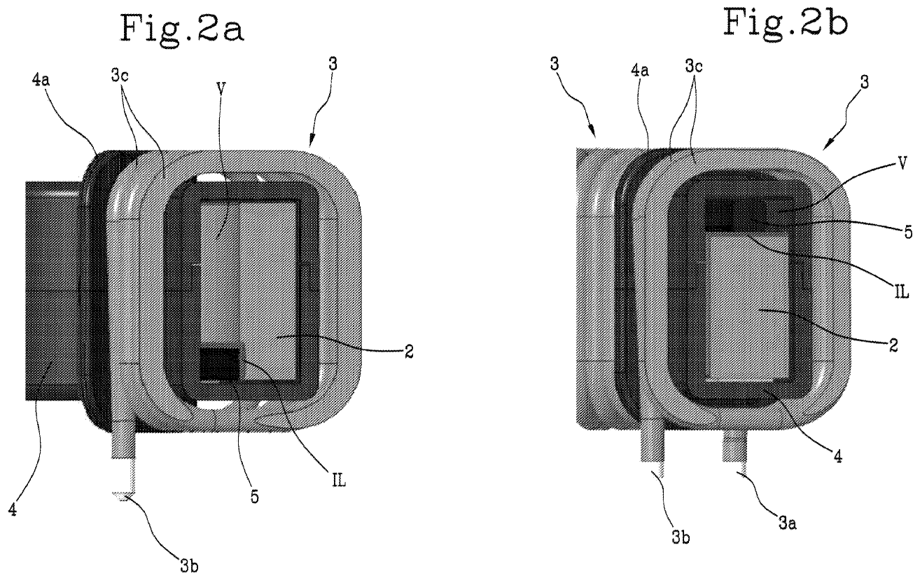

FIG. 2a shows a transverse section of a detail of the device in FIG. 1;

FIG. 2b shows a variant of the configuration in FIG. 2a;

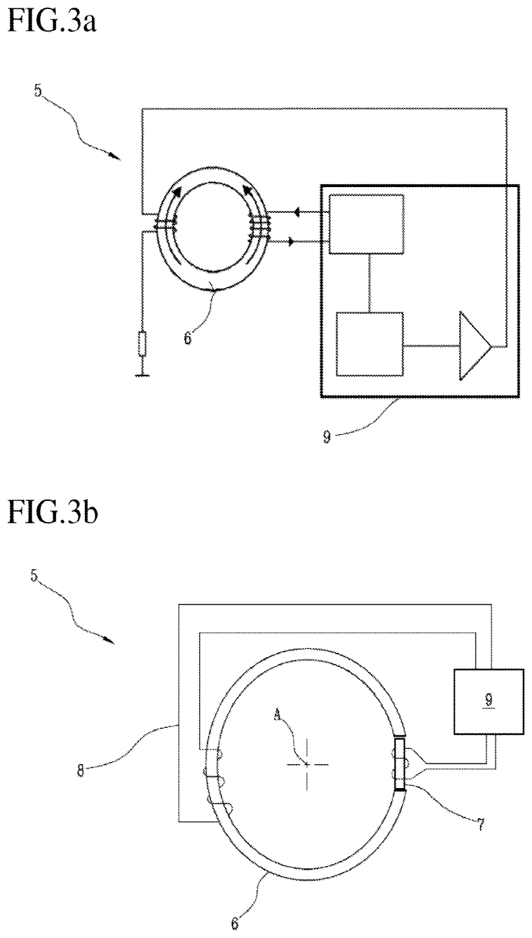

FIGS. 3a and 3b show, schematically, the layout of a component of the device in FIG. 1 in two different, alternative embodiments;

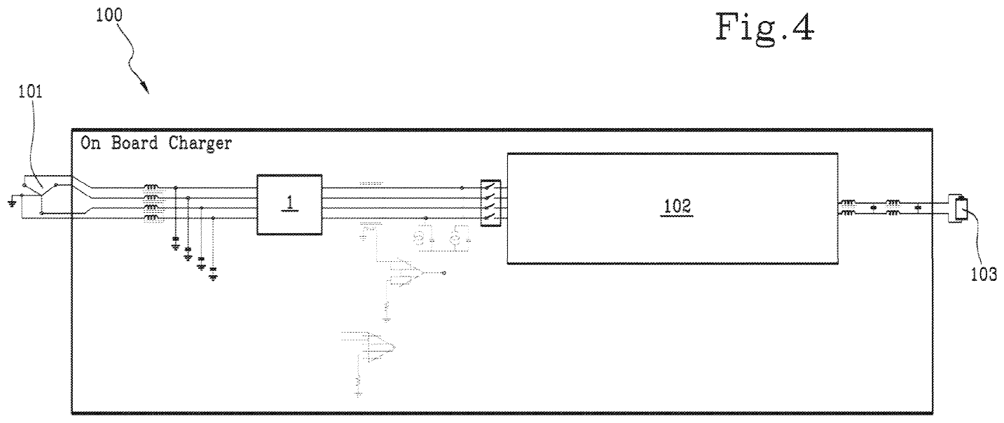

FIG. 4 schematically shows the electrical layout of a system for charging electric or hybrid vehicles in accordance with the invention.

With reference to the appended figures, the reference number 1 indicates, generically, a common mode current filter according to this invention.

The filter 1 is of the type configured to lower or reduce electromagnetic or radio-frequency disturbances coming from the network.

This filter 1 is preferably positioned on the supply branch or network branch of a more complex system, preferably a charging system 100 of a battery pack 103 for electric or hybrid vehicles.

In the preferred embodiment, the charging system 100 comprises at least one connection 101 to the electricity network and a converter assembly 102.

If there is an on-board charger, the connection could be defined by a socket 101, like that schematically illustrated in FIG. 4.

The converter assembly 102 is arranged operationally downstream of the socket and is configured to convert an alternating current coming from the electricity network into a direct current that can be used for recharging a battery pack 103.

The converter assembly preferably comprises power factor correction (PFC), configured to convert from alternating current to direct current, and a device for regulating the charge current to the battery back (Buck).

This regulating device is preferably a DC-DC converter configured to modulate the charging current as a function of the battery needs.

The filter 1 is positioned between the socket 101 and the converter assembly 102, so as to limit, as much as possible, the disturbances that reach the conversion stage from the mains or nearby equipment.

This function is carried out by the structure of the device 1, which is shaped so as to “block” the unwanted non-differential currents.

From the structural point of view, the filter 1 comprises a magnetic core 2 made of any material with sufficient magnetic properties, such as, for example, ferrite, iron, or its alloys, as well as, preferably, nanocrystalline material.

Examples of nanocrystalline material useful for the purpose may be found in the literature and are known in themselves.

This magnetic core 1 preferably has a ring shape, with, more preferably, a circular configuration.

In these embodiments, not illustrated, this magnetic core 2 has a toroidal shape.

The magnetic core 2 extends, thus, along its own “closed” extension direction, shaped like a ring around a central axis “A”.

At least two electrical windings 3 are wound around the magnetic core 2, each extending between two ends 3a, 3b and comprising multiple coils 3c.

In the preferred embodiment, illustrated by way of example in the attached figures, the filter 1 comprises four electrical windings 3, one for each phase of the three-phase network, together with the neutral.

Alternatively, in any case, the windings could also be of a different number, depending on the application and current source.

Each winding 3 is, thus, preferably made of a copper wire (or other electrically conductive material) at least in part wound around the magnetic core 2, or around the core's extension direction.

Given the preferred ring shape of the core, the windings 3 are preferably spaced angularly apart, more preferably equally spaced apart, around said central axis “A”.

Depending on the number of windings and of the type of supply, in addition, the direction and position of the windings may be different (consistent or “mirrored”, for example).

In the embodiment illustrated, the direction of the windings is consistent.

During normal operation, the current through each winding is equal or contrary (or out-of-phase). Due to the arrangement of the windings, the magnetic fields of the core are eliminated. This enables the common mode inductor to have high impedance only for those non-differential components, e.g., the common mode components, of the currents coming from the mains.

This also means that the core is not saturated even for large differential mode currents.

In addition, the filter 1 preferably comprises a casing 4 made of electrical insulating material and defining, inside, a housing volume “V” for the magnetic core 2.

The casing 4 is, thus, physically positioned between the magnetic core 2 and the windings 3, so as to insulate them electrically.

The casing 4 is preferably made of plastic, such as PBT or PPS for example.

The casing 4 extends, thus, along its own extension direction, preferably ring-shaped, aligned with the extension direction of the magnetic core 2.

Therefore, the casing 4 preferably extends in a ring, more preferably circularly, around the central axis “A” of the magnetic core 2.

It should be noted that the term “in a ring” is not supposed, in this text, to define that the casing (like the other components thus defined) extends around a central axis, without, necessarily, identifying a precise geometry thereof.

The extension is preferably closed, except for small cuts/spaces useful for the operations of the elements and, in any case, negligible in relation to the circumferential extension of the component.

The ring-shaped extension is, preferably, also circular or elliptical, but could, equally, be polygonal (e.g., square or rectangular).

The casing 4 is, therefore, a basically ring-shaped casing defining, inside, a ring-shaped or toroidal volume “V” for housing the magnetic core 2.

To enable a correct and simple positioning of the windings 3, preferably, the casing 4 preferably has multiple transverse partitions 4a equally angularly spaced apart designed to divide it into multiple corresponding distinct sections “S”.

The number of partitions is, preferably, proportional, in particular corresponding, to the number of windings 3.

In the preferred embodiment, there are four transverse partitions 4a and they divide the casing 4 into four sections “S” around which the corresponding electrical windings 3 are wound.

In other words, the filter 1 comprises four electrical windings 3, each wound around a corresponding section “S” of the casing 4.

It should be noted that, in one embodiment not illustrated, the device 1 could be free of a “rigid” casing in a narrow sense, in which the magnetic core 2 is coated with an insulating layer (potentially a resin).

According to the invention, the filter 1 comprises a fluxgate magnetometer positioned within the coils 3c of each electrical winding 3.

In other words, the filter 1 comprises a single fluxgate magnetometer 5 that crosses at least one coil 3c (preferably all the coils) of each winding 3.

Advantageously, in this way, the presence of the windings that carry the mains current to the filter 1 is exploited as useful current sources for measuring any unbalances useful for monitoring and required by the safety standards.

The fluxgate magnetometer 5 preferably extends in a ring around the central axis “A”. With reference to the adverbial phrase “in a ring”, please refer to the definition of “ring-shaped” offered above.

More preferably the fluxgate magnetometer 5 extends parallel and/or concentrically to said magnetic core 2.

Advantageously, in this way, the dimensions are minimised and the assembly is simplified.

It should be noted that the fluxgate magnetometer 5, as long as it is arranged around the central axis “A” and crossing the coils 3c of the windings, may be positioned in any position in relation to the magnetic core 2.

In some embodiments, the fluxgate magnetometer 5 is positioned radially internal to the magnetic core 2 (FIG. 2a), or in a radially external position (not illustrated).

Alternatively, the fluxgate magnetometer 5 could be positioned at the same radial level but axially shifted in relation to the magnetic core 2 (FIG. 2b).

In the preferred embodiments, the fluxgate magnetometer 5 and the magnetic core 2 are both housed inside the casing 4, separated from each other by at least one electrical insulating layer “IL”.

In more detail, the casing 4 preferably comprises first anchoring means (not illustrated) and second anchoring means (not illustrated) designed to respectively fix the magnetic core 2 and the fluxgate magnetometer 5 inside the housing volume “V”.

The first and second anchoring means may be defined by holding elements produced (via moulding) on the inner walls of the casing that, together with a greater or lesser distribution of resin, hold the magnetic core 2 and the fluxgate magnetometer 5 in position.

Between the magnetic core 2 and the fluxgate magnetometer 5, there is, as mentioned, at least one electrical insulating layer “IL”, designed to avoid electric and magnetic contact between the two elements and having a predetermined thickness.

Said predetermined thickness is preferably proportional to a ratio between the magnetic permeability of the magnetic core 2 and the magnetic permeability of the fluxgate magnetometer 5.

It should be noted that the casing 4 could also be defined by two distinct bodies, i.e., two casings dedicated to the magnetic core 2 and the fluxgate magnetometer 5 bound together at what could be considered the electrical insulating layer “IL”.

Preferably, then, the fluxgate magnetometer comprises a core 6 crossed by at least one coil 3c of each electrical winding 3.

The core 6, made of magnetic material (e.g., MuMetal®), is thus, basically, ring-shaped, so as to cross all the windings.

Around this core 6 a winding 8 is wound connected to a processing unit 9 set up to drive it.

In some (open loop) embodiments, the winding 8 is driven alternately to continuously saturate the magnetic core with a predefined hysteresis cycle in order to enable the assessment of any unbalances introduced by the current circulating in the multiple windings 3.

One example of this magnetometer is schematically illustrated in FIG. 3a.

The magnetometer is preferably driven with a square wave through a drive winding. The core is, thus, continuously brought to saturation, verifying any unbalance of the cycle (e.g., duty cycle variation) owing to the magnetic field induced by the electrical windings 3. This embodiment preferably involves all the wires of the electrical windings passing inside the core so as to reduce the sensitivity of the magnetometer to factors independent of the field (e.g., temperature, material, etc.).

In the preferred embodiment, and illustrated in FIG. 3b, the fluxgate magnetometer 5 is of the compensation, closed-ring type, which advantageously enables an efficient detection of currents, even very small ones, of the order of milliampere (mA).

The presence of a magnetic field probe 7 is, thus, preferably provided, one that is connected to the core 6 and designed to detect the magnetic field generated by the (common mode) current flowing in the windings 3.

In addition, the winding 8 of the fluxgate magnetometer 5 is, preferably, a compensation winding and the processing unit 9 is connected both to said compensation winding 8 and to the probe 7.

In use, the processing unit 9 is configured to drive the (compensation) winding 8 so as to compensate for the unbalances of the magnetic field detected by said magnetic field probe 7.

It should be noted, in this respect. that in the embodiment of FIG. 3a, the presence of the magnetic field probe is not necessary since the field is deducted from the unbalance of the hysteresis cycle.

The invention achieves the purposes proposed and entails significant advantages.

In fact, the arrangement of a filter integrated with a device for detecting the current (residual current detector) such as the fluxgate magnetometer of the invention, makes it possible to provide an extremely efficient and versatile device, which can be used to optimise the functionalities of a charging system for vehicles, whether it is on-board or a ground system (column or wall-box), without negatively affecting the dimensions and cost of the system.

In particular, the arrangement of a component necessary to ensure the safety in the on-board charging systems of electric or hybrid vehicles, such as the fluxgate magnetometer, inside of an element already present in the circuit (common mode filter), makes the management of space (they are bulky devices) and temperatures significantly more efficient, making the configuration that is the subject of this patent particularly attractive.

1. A common mode current filter comprising:
a magnetic core;
multiple electrical windings, each extending between two ends and comprising multiple coils wound around said magnetic core;
wherein it comprises a fluxgate magnetometer provided with a core made of magnetic material and positioned inside the coils of each electrical winding.

2. The filter according to claim 1, wherein the magnetic core and the core of the fluxgate magnetometer are basically ring shaped along respective main directions and around a common central axis.

3. The filter according to claim 1, wherein the core of the fluxgate magnetometer extends parallel to said magnetic core.

4. The filter according to claim 1, comprising a casing made of electrical insulating material and defining a housing volume within, wherein the magnetic core is housed inside said housing volume and the coils of each winding are wound outside said casing.

5. The filter according to claim 4, wherein the core of the fluxgate magnetometer and the magnetic core are both housed inside the casing, separated from each other by at least one electrical insulating layer.

6. The filter according to claim 4, wherein the casing comprises:
first anchoring means designed to fix the magnetic core inside the housing volume;
second anchoring means designed to fix the core of the fluxgate magnetometer inside the housing volume;
said electrical insulating layer placed between said magnetic core and said core of the fluxgate magnetometer.

7. The filter according to claim 4, wherein the casing is shaped so as to define multiple sections angularly spaced between them and designed to each house an electrical winding of said multiple electrical windings.

8. The filter according to claim 4, wherein:
the casing is basically ring or toroidal shaped provided with at least four transverse partitions angularly spaced between them and designed to divide it into four distinct sections;
said multiple electrical windings comprise four electrical windings, each wound around a corresponding section of the casing.

9. The filter according to claim 1, wherein said core of the fluxgate magnetometer is crossed by at least one coil of each electrical winding of said multiple electrical windings;
said fluxgate magnetometer also comprising:
a winding wound around said core;
a processing unit connected to said winding and configured to drive it.

10. The filter according to claim 9, wherein the fluxgate magnetometer also comprises a magnetic field probe connected to the core and configured to detect a magnetic field generated by a common mode current flowing in the windings; said processing unit being configured to drive the winding so as to compensate the unbalances of the magnetic field detected by said magnetic field probe.

11. A system for charging electric or hybrid vehicles, comprising at least one socket to an electricity network and containing a converter assembly configured to convert alternating current coming from the electricity network into direct current that can be used to recharge a battery pack, characterised in that it comprises at least one filter according to claim 1 operationally placed between said socket and said converter assembly.
